(19) United States
(12) Patent Application Publication
(10) Pub. No.: US 2025/0275257 A1
(43) Pub. Date: Aug. 28, 2025

(54) ELECTROSTATIC DISCHARGE PROTECTION DEVICE AND DISPLAY DEVICE INCLUDING SAME

(71) Applicant: LG Display Co., Ltd., Seoul (KR)

(72) Inventors: Do Hun KWAK, Paju-si (KR); Min Gu KANG, Paju-si (KR); Ki Tae KIM, Paju-si (KR); Dae Hwan KIM, Paju-si (KR)

(73) Assignee: LG Display Co., Ltd., Seoul (KR)

(21) Appl. No.: 19/065,712

(22) Filed: Feb. 27, 2025

(30) Foreign Application Priority Data
Feb. 28, 2024 (KR) 10-2024-0029195

(51) Int. Cl. H10D 89/60; H10H 29/32; H10H 29/855

(52) U.S. Cl. CPC H10D 89/811; H10H 29/32; H10H 29/8552

(57) ABSTRACT

An electrostatic discharge protection device can include a first electrode extending in a first direction, an active layer, and a second electrode. The active layer has a first width in the first direction, and overlaps the first electrode. The active layer includes at least one hole in an overlapping region, and is disposed longer outwardly than one or more sides of the first electrode in a second direction intersecting the first direction. The second electrode is disposed side by side with the first electrode and includes a first connection portion to one side of the active layer.

### CROSS-REFERENCE TO RELATED APPLICATIONS

This application claims priority to Korean Patent Application No. 10-2024-0029195, filed in the Republic of Korea on Feb. 28, 2024, which is hereby expressly incorporated by reference into the present application.

### BACKGROUND OF THE DISCLOSURE

### Technical Field

The present disclosure relates to an electrostatic discharge protection device, and more particularly to an electrostatic discharge protection device having efficient heat dissipation and improved reliability, and a display device including the same.

### Discussion of the Related Art

Display devices that display images, such as TVs, monitors, smartphones, tablet computers, and laptops, are used in various ways and forms.

The display device includes a plurality of pixels to display an image and has transistors to control the operation of each pixel. The display device is provided with wiring and driving circuits connected to transistors to apply various signals to drive the pixels.

Research and development is ongoing into protection devices to prevent damage to the wirings and driving circuits which can be caused by static electricity, which can result in malfunction of the wiring and driving circuits.

### SUMMARY OF THE DISCLOSURE

An object of the present disclosure is to provide an electrostatic discharge protection device capable of preventing heat in an active layer from being concentrated in a specific area.

Another object of the present disclosure is to provide an electrostatic discharge protection device capable of spreading heat generated from an active layer and easily dissipating heat to the outside.

Still another object of the present disclosure is to provide an electrostatic discharge protection device, in which heat spreading and heat dissipation of an active layer are possible in an electrostatic discharge protection device including a high-mobility oxide semiconductor, increasing breakdown voltage of the electrostatic discharge protection device and improving reliability thereof.

Yet another object of the present disclosure is to provide an electrostatic discharge protection device, which can be manufactured through the same process as transistors of an active area, and enables the addition of a heat dissipation path by forming a pattern of an active layer or a contact hole between an electrode layer and an active layer without any additional process, thereby preventing or minimizing a change in a conductive area due to heat concentration in a channel without harmful gases or additional materials and improving breakdown voltage.

Still yet another object of the present disclosure is to provide a display device including an electrostatic discharge protection device capable of improving durability of the electrostatic discharge protection device and operational stability of the display device by stabilizing a signal input via the electrostatic discharge protection device.

A further object of the present disclosure is to provide an electrostatic discharge protection device configured to prevent or minimize conductive diffusion that can be aggravated by heat when applied to a transistor having a wide channel, thus solving or addressing the problems and limitations of threshold voltage sensitivity in wide devices due to a change in channel length caused by conductive diffusion, thereby improving reliability of a transistor by controlling a change in the effective channel length of a transistor including an oxide semiconductor.

Still a further object of the present disclosure is to provide an electrostatic discharge protection device capable of minimizing a channel length margin when forming a wide transistor, thereby enabling operation at low power compared to a structure with a channel length margin.

Yet a further object of the present disclosure is to provide a display device in which a wide transistor having device stability is included in an active area or a non-active area.

Still yet a further object of the present disclosure is to provide a display device having a high degree of design freedom by reducing threshold voltage sensitivity depending on a change in channel width, thus achieving a narrow bezel by disposing a high-output transistor in a small size in a non-active area.

An embodiment of the present disclosure provides an electrostatic discharge protection device including a first electrode disposed long in a first direction; an active layer, which has a first width in the first direction, overlaps the first electrode, includes at least one hole in the overlapping region, and is disposed longer outwardly than both sides of the first electrode in a second direction intersecting the first direction; and a second electrode disposed side by side with the first electrode and having a first connection portion to one side of the active layer.

In the electrostatic discharge protection device according to an embodiment of the present disclosure, the active layer can have at least one heat spreading pattern protruding outwardly in the second direction.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a schematic plan view showing a display device according to one or more embodiments of the present disclosure;

FIG. 2 is a circuit diagram showing a sub-pixel according to an embodiment of the present disclosure;

FIG. 3 is a circuit diagram showing an electrostatic discharge protection device according to an embodiment of the present disclosure;

FIG. 4 is a plan view showing an electrostatic discharge protection device according to a first embodiment of the present disclosure;

FIG. 5 is a cross-sectional view along line I-I′ of FIG. 4;

FIG. 6 is a cross-sectional view along line II-II′ of FIG. 4;

FIGS. 7A to 7D are plan views showing various examples of active layers including holes according to aspects of the present disclosure;

FIG. 8 is a plan view showing an electrostatic discharge protection device according to a second embodiment of the present disclosure;

FIG. 9 is a plan view showing an electrostatic discharge protection device according to a third embodiment of the present disclosure;

FIG. 10 is a cross-sectional view along line III-III′ of FIG. 9;

FIG. 11 is a modification of the third embodiment of the present disclosure;

FIG. 12 is a plan view according to a fourth embodiment of the present disclosure;

FIG. 13 is a cross-sectional view along line IV-IV′ of FIG. 12;

FIG. 14 is a plan view according to a fifth embodiment of the present disclosure;

FIG. 15 is a cross-sectional view along line V-V′ of FIG. 14;

FIG. 16 is a modification of the fifth embodiment of the present disclosure;

FIG. 17A is graphs showing an example of the results of evaluation of breakdown voltage of an electrostatic discharge protection circuit without heat dissipation means;

FIG. 17B is a graph showing an example of the results of evaluation of breakdown voltage of the electrostatic discharge protection circuit according to an embodiment of the present disclosure; and

FIG. 18 is a cross-sectional view showing a display device according to one or more embodiments of the present disclosure.

### DETAILED DESCRIPTION OF THE EMBODIMENTS

Hereinafter, various embodiments of the present disclosure will be described with reference to the attached drawings. The same reference numerals indicate substantially the same elements throughout the specification. In the following description of the present disclosure, where the detailed description of the relevant known steps, elements, functions, technologies, and configurations can unnecessarily obscure an important point of the present disclosure, a detailed description of such steps, elements, functions, technologies, and configurations can be omitted. In addition, the names of elements used in the following description are selected in consideration of clarity of description of the specification, and can differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings. In the present disclosure, where terms such as “including,” “having,” “comprising,” and the like are used, one or more components can be added, unless the term, such as “only,” is used. The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise. Further, the term “can” fully encompasses all the meanings and coverages of the term “may.”

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

An electrostatic discharge protection device and a display device including the same according to embodiments of the present disclosure will now be discussed below. Each device according to all embodiments of the present disclosure are operatively coupled and configured.

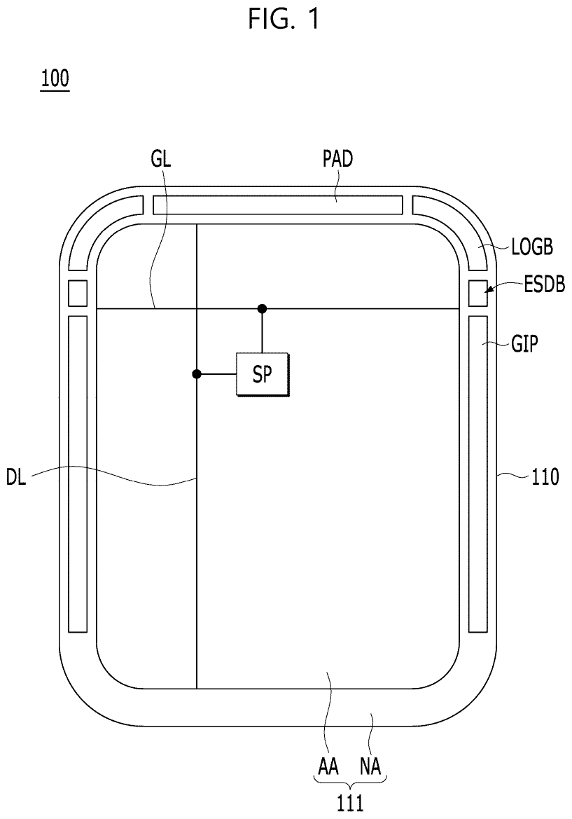

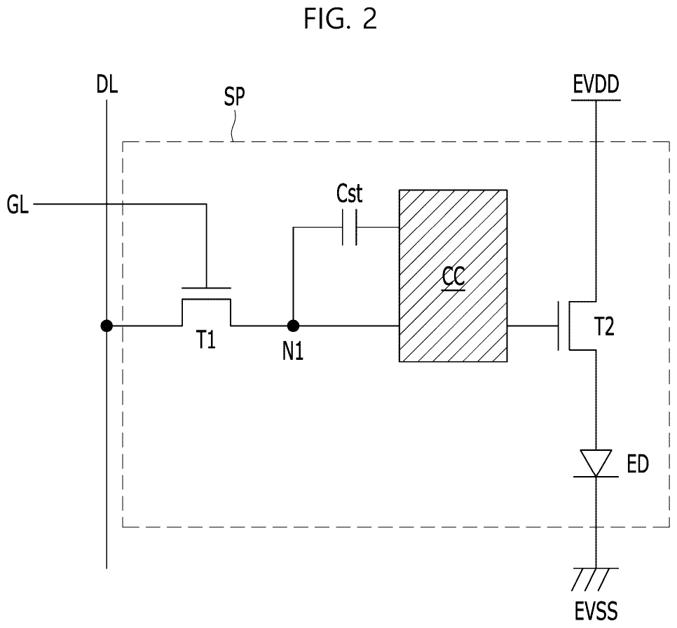

FIG. 1 is a schematic plan view showing a display device according to one or more embodiments of the present disclosure, and FIG. 2 is a circuit diagram showing a sub-pixel according to an embodiment of the present disclosure.

Referring to FIGS. 1 and 2, a display device 100 according to an embodiment of the present disclosure includes a display panel 110, and the display panel 110 can include a substrate 111 including an active area AA (or display area) and a non-active area NA (or non-display area) surrounding the active area AA, and a driver connected to the substrate 111. The driver can be formed by being integrated into the substrate 111 together with components in the array provided in the active area AA, or can be connected to the substrate 111 in a COG (chip on glass) manner or can be connected to a printed circuit board through a film or connector in a COF (chip on film) manner on the substrate 111.

The active area AA is the area where the image is displayed. A plurality of sub-pixels SP is arranged in the active area AA of the display panel 110, and an image can be displayed using the sub-pixels SP.

The display device 100 can include a display panel 110 and a case that accommodates a side of the display panel 110 and a bottom of the display panel 110. The non-active area NA of the display panel 110 can be hidden by the case or can be covered with a separate printed film. A printed circuit film and/or a battery can be included between the bottom of the display panel 110 and the case.

The area where sub-pixels SP are arranged can be an active area AA, and the area other than the active area AA can be a non-active area NA.

The non-active area NA can be disposed in the edge surrounding the active area AA that displays the image. The non-active area NA can surround the active area AA entirely or only part(s).

At least one driver configured to drive the sub-pixels SP can be disposed in the non-active area NA. The driver can include a gate driver configured to supply a gate signal to a gate line GL and a data driver configured to supply a data signal to a data line DL. For example, the display device 100 can include a gate-in-panel GIP provided directly on the substrate 111 within the display panel 110 as a form of the gate driver. The gate-in-panel GIP can be formed through the same process as transistors, capacitors, wiring, etc. included in the active area AA.

The gate-in-panel GIP can be connected to a plurality of gate lines GL of the active area AA and can serve to sequentially supply gate voltage signals to the gate lines GL.

The data driver can be, for example, in the form of a data IC (integrated circuit). The data IC can be connected to a pad portion PAD located on one side of the non-active area NA in a COF (chip on film) manner or COG (chip on glass) manner. The data IC can be connected to a printed circuit board including a timing controller at one side thereof.

Further, a line-on-glass block LOGB and an electrostatic discharge protection block ESDB can be provided between the gate-in-panel GIP and the pad portion PAD.

The wires in the line-on-glass block LOGB serve to connect the data IC and the gate-in-panel to each other. Various clock signals and power voltage signals of the printed circuit board can be transmitted to the gate-in-panel GIP through the data IC and the line-on-glass block LOGB.

Since various types of voltage signals are transmitted to the gate-in-panel GIP through the line-on-glass block LOGB and high-voltage signals are adjacently applied, the influence of electrostatic discharge can be significant, so an electrostatic discharge protection block ESDB can be provided between the line-on-glass block LOGB and the gate-in-panel GIP.

An electrostatic discharge protection device can be further provided around the pad portion PAD in addition to the area shown in FIG. 1.

As display devices become higher resolution and larger in area, the wiring and circuits included in the substrate 111 become more integrated, and the non-active area can gradually become narrower. Accordingly, the area allocated to the electrostatic discharge protection device is also reduced.

Embodiments of the present disclosure have structural features that enable heat dissipation of an electrostatic discharge protection device provided in a limited area.

Various additional elements can also be disposed in the non-active area NA to drive the sub-pixels SP within the active area AA.

At least one sub-pixel SP among a plurality of pixels can include a first transistor T1, a second transistor T2, a storage capacitor Cst, a compensation circuit CC, and a light emitting device ED, as shown in FIG. 2.

For example, the first transistor T1 can be a switching transistor and the second transistor T2 can be a driving transistor.

A first electrode (e.g., a drain electrode) of the first transistor T1 is electrically connected to a data line DL, and a second electrode (e.g., a source electrode) thereof is electrically connected to a first node N1. The gate electrode of the first transistor T1 is electrically connected to a gate line GL. The first transistor T1 serves to transmit a data signal supplied through the data line DL to the first node N1 in response to a scan signal supplied through the gate line GL.

The storage capacitor Cst is electrically connected to the first node N1 and serves to charge the voltage applied to the first node N1.

A first electrode (e.g., a drain electrode) of the second transistor T2 receives a high potential driving voltage EVDD, and a second electrode (e.g., a source electrode) thereof is electrically connected to a first electrode (e.g., an anode) of the light emitting device ED. The second transistor T2 can serve to control the quantity of driving current flowing to the light emitting device ED in response to voltage applied to the gate electrode.

The semiconductor layer of the first transistor T1 and/or the second transistor T2 can include silicon such as amorphous silicon (a-Si), polycrystalline silicon (poly-Si), or low-temperature polycrystalline silicon (poly-Si), or can include an oxide such as indium-gallium-zinc-oxide (IGZO), but is not limited thereto. At least one of the first transistor T1 or the second transistor T2 can include an oxide semiconductor layer, enabling formation at a low temperature compared to other materials, maintaining amorphous characteristics, and exhibiting high mobility.

The light emitting device ED serves to output light corresponding to the driving current. The light emitting device ED is able to output light corresponding to any one color selected from among the colors red, green, blue, and white.

The light emitting device ED can include an anode, an intermediate layer disposed on the anode, and a cathode configured to supply a common voltage. The intermediate layer can include at least one emission layer, making it possible to emit light of the same color for each pixel, such as white light, or to emit light of a different color for each sub-pixel SP, such as red, green, or blue light. The intermediate layer can include various types of common layers and functional layers to efficiently supply holes and electrons to the emission layer. A second electrode (e.g., a cathode) of the light emitting device ED receives a low potential driving voltage EVSS.

The light emitting device ED can be a top emission diode or a bottom emission diode.

The compensation circuit CC can be additionally provided in the sub-pixel SP to compensate for the threshold voltage of the second transistor T2, etc. The compensation circuit CC can be composed of one or more transistors. The compensation circuit CC can include one or more transistors and capacitors and can be configured in various ways depending on the compensation method. A sub-pixel SP including the compensation circuit CC can include circuits with various structures having different numbers of transistors and/or capacitors, such as 3T1C, 4T2C, 5T2C, 6T1C, 6T2C, 7T1C, 7T2C, etc.

Below is a description of an electrostatic discharge protection device according to an embodiment of the present disclosure and a display device including the same. The electrostatic discharge protection device can be formed through the same process as the transistors included in sub-pixels and the gate-in-panel GIP.

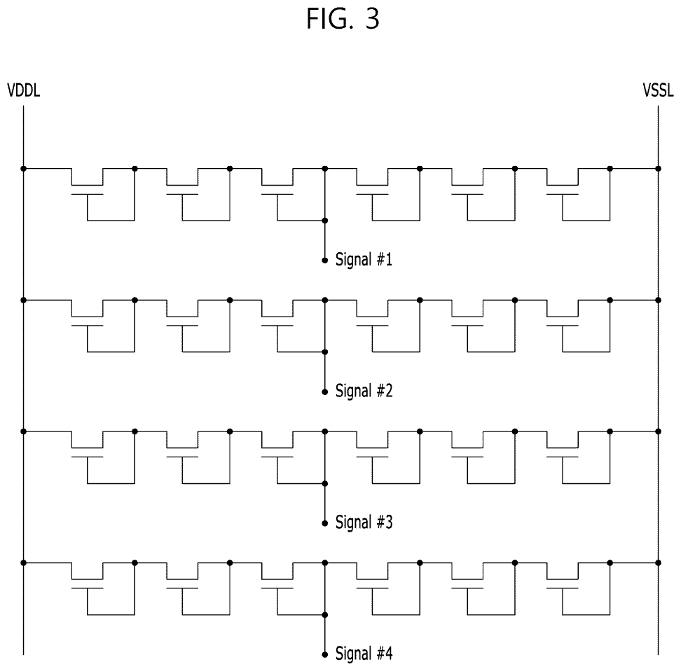

FIG. 3 is a circuit diagram showing an electrostatic discharge protection device according to an embodiment of the present disclosure.

As shown in FIG. 3, the electrostatic discharge protection device according to an embodiment of the present disclosure is configured such that rows, in which six transistors each including a gate electrode and a source electrode connected each other are connected in series, are repeatedly arranged between a high voltage line VDDL and a low voltage line VSSL.

The leftmost transistor in each row is configured such that a first source/drain electrode (drain electrode) is connected to the high voltage line VDDL, and a second source/drain electrode (source electrode) is connected to the first source/drain electrode (drain electrode) of the next transistor. In the same way, adjacent transistors are configured such that the second source/drain electrode (source electrode) of the previous transistor is connected to the first source/drain electrode (drain electrode) of the next transistor. The rightmost transistor in each row is configured such that a second source/drain electrode (source electrode) is connected to the low voltage line VSSL. The gate electrodes and source electrodes of the transistors are connected.

Each row connected to the high voltage line VDDL and the low voltage line VSSL can have the same configuration.

When an external signal (Signal #1, Signal #2, Signal #4, Signal #4) caused by static electricity, etc., is input through the gate electrode of any one of the transistors in each row, current can flow along a current path from the high voltage line VDDL to the low voltage line VSSL, and static electricity can be discharged.

Although an example in which six transistors are provided in each row is illustrated, the number of transistors provided in the electrostatic discharge protection device is not limited thereto. FIG. 3 illustrates the electrostatic discharge protection device having four rows connected to the high voltage line VDDL and the low voltage line VSSL, but the present disclosure is not limited thereto.

Various embodiments of the electrostatic discharge protection device according to the present disclosure are described below.

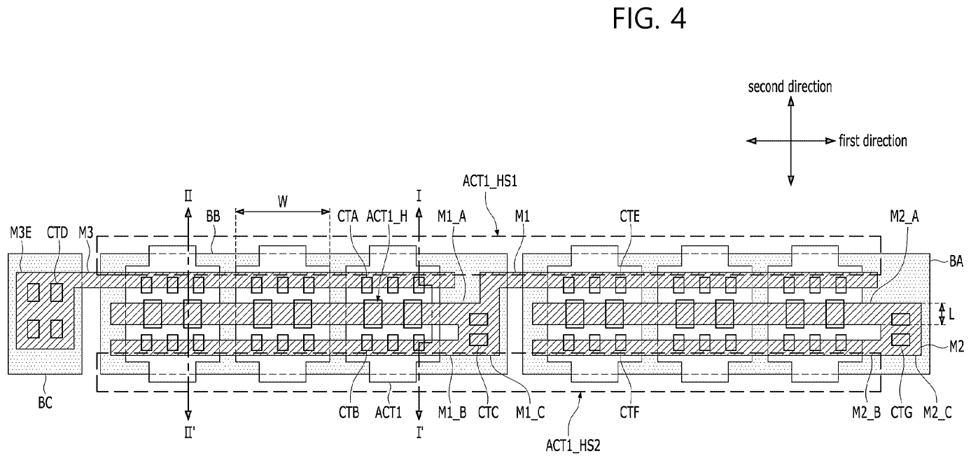

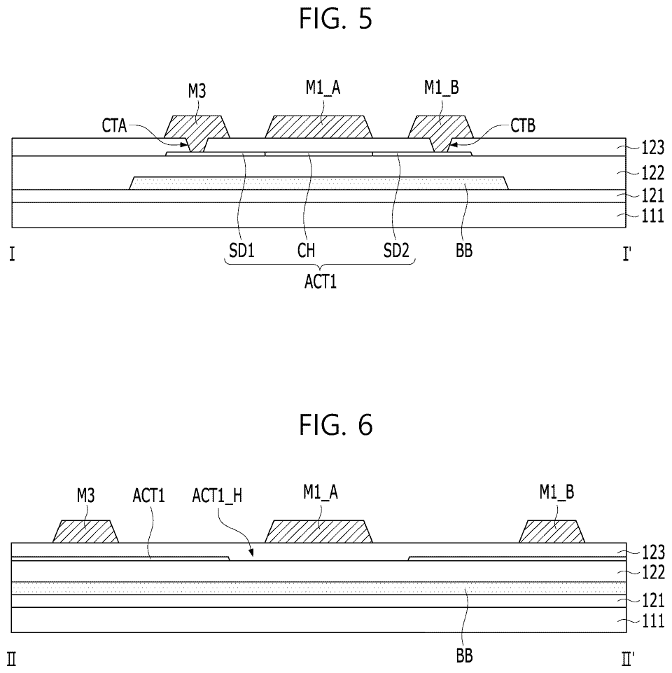

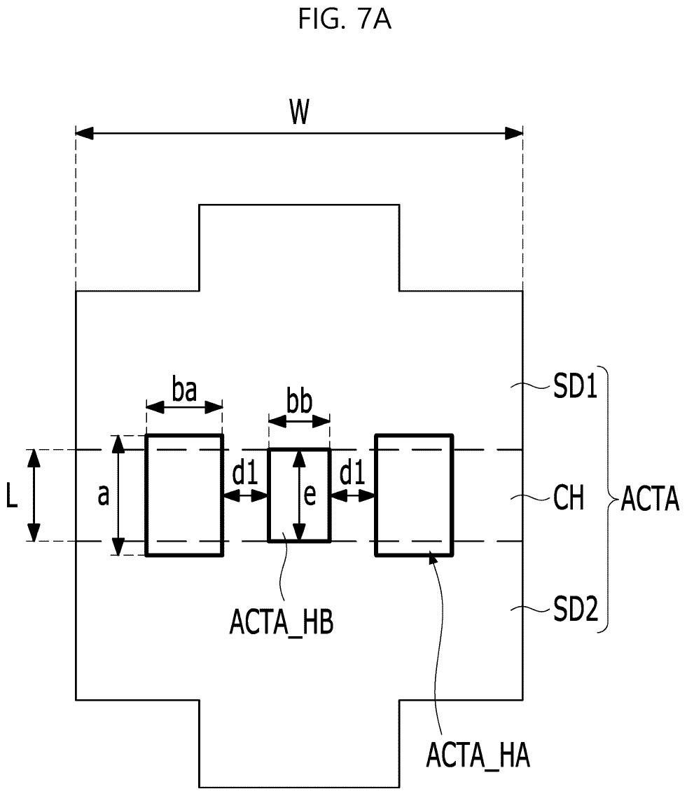

FIG. 4 is a plan view showing an electrostatic discharge protection device according to a first embodiment of the present disclosure, FIG. 5 is a cross-sectional view along line I-I′ of FIG. 4, and FIG. 6 is a cross-sectional view along line II-II′ of FIG. 4.

As shown in FIG. 4, the electrostatic discharge protection device according to an embodiment of the present disclosure can include first electrodes M1_A, M2_A disposed long in a first direction (arrow direction of W), and active layers ACT1 having a first width W in the first direction and overlapping the first electrodes M1_A, M2_A. The active layers ACT1 include at least one hole ACT1_H in the overlapping region, and are disposed longer outwardly (e.g., protrude outwardly or further) than both sides (e.g., opposite sides) of the first electrodes M1_A, M2_A in a second direction (arrow direction of II-II′) intersecting the first direction. The electrostatic discharge protection device can further include second electrodes M3, M1 disposed side by side with the first electrodes M1_A, M2_A and connected to one side of the active layers ACT1.

The active layers ACT1 each having a first width W in the first direction can be spaced apart from each other.

The active layers ACT1 can overlap the first electrodes M1_A, M2_A by a first length L in the second direction intersecting the first direction, can have a channel region with the first width W and the first length L, and can have source/drain regions at both sides of the channel region in the second direction.

One side of the source/drain regions of the active layers ACT1 is connected to the second electrodes M3, M1.

The remaining side of the source/drain regions of the active layers ACT1 can be connected to third electrodes M1_B, M2_B. The third electrodes M1_B, M2_B can be disposed side by side with the first electrodes M1_A, M2_A and the second electrodes M3, M1, and can be located at positions facing the second electrodes M3, M1 with the first electrodes M1_A, M2_A therebetween. For example, the second electrodes M3, M1 have portions connected to one side of the active layer ACT1, and the third electrodes M1_B, M2_B have portions connected to another side of the active layer ACT1. Herein, the portion of the second electrodes M3, M1 connected to one side of the active layer ACT1 may be referred as “a first connection portion”, and the portion of the third electrodes M1_B, M2_B connected to another side of the active layer ACT1 (or connected to the active layer ACT1 at a position opposite to the first connection portion) may be referred as “a second connection portion”.

In the electrostatic discharge protection device according to the embodiment of FIG. 4, transistors in which the first electrodes M1_A, M2_A are used as gate electrodes and the second electrodes M3, M1 and the third electrodes M1_B, M2_B at both sides are used as respective first and second source/drain electrodes are provided corresponding to respective active layers ACT1.

Further, the first electrodes M1_A, M2_A of the transistors can have the same node by being electrically connected to the third electrodes M1_B, M2_B. This configuration is the same as the configuration of each transistor of FIG. 4 in which the gate electrode and the source electrode are connected.

Meanwhile, the active layers ACT1 are provided with at least one hole ACT1_H in the region overlapping the first electrodes M1_A, M2_A so as to spread heat generated from each transistor and spread an electric field around the hole.

To more effectively spread heat and electric field, the hole ACT1_H can be distributed in a portion of the channel of each of the active layers ACT1 and a portion of the source/drain region around the channel. Here, multiple holes ACT1_H can be provided in complementary positions.

The hole ACT1_H distributed in the portion of the channel and the region around the channel allows heat generated in and around the channel to be spread around the hole, and allows Joule heating flowing through the active layers ACT in the electrostatic discharge protection device to be spread. In this way, the structure of the active layer including the hole ACT1_H is called a PAL (punched active layer) structure, and embodiments of the present disclosure are characterized in that a separate heat spreading structure is also provided in addition to the hole ACT1_H of the active layer ACT1, considering that a high-voltage and high-current external signal is applied during electrostatic discharge. Another feature of the PAL structure is that Joule heating can be dissipated through the hole during driving of the transistor. Accordingly, in contrast to a phenomenon in which threshold voltage shifts in the negative direction due to a change ΔL in channel length L of the channel in a structure in which Joule heating is not dissipated, the transistor according to an embodiment of the present disclosure can effectively dissipate heat by forming a hole ACT1_H in the active layer ACT1 and a heat spreading structure, thereby preventing the threshold voltage from changing.

The hole ACT1_H can be provided in a portion of the channel region to extend to the entire channel length L and a portion outside the channel region, but embodiments of the present disclosure are not limited thereto. The hole ACT1_H can be provided only in a portion of the channel length L. The hole ACT1_H can be provided corresponding to the channel length L. Various embodiments of the hole are described later.

A third insulating film 123 is provided on the hole ACT1_H, so that the first electrodes M1_A, M2_A can be insulated from the lower configuration in the area where the hole ACT1_H is located.

In the electrostatic discharge protection device according to an embodiment of the present disclosure, a plurality of active layers ACT1 is disposed in the first direction and overlaps the first electrodes M1_A, M2_A, the second electrodes M3, M1, and the third electrodes M1_B, M2_B, and a transistor is provided for each active layer ACT1.

Meanwhile, in the electrostatic discharge protection device according to an embodiment of the present disclosure, the active layer ACT1 can have at least one heat spreading pattern ACT1_HS1, ACT1_HS2 protruding outwardly in the second direction. FIG. 4 shows an example in which heat spreading patterns ACT1_HS1, ACT1_HS2 are located at both sides of the active layers ACT1. The heat spreading patterns ACT1_HS1, ACT_HS2 are provided at both sides of the active layers ACT1 in the direction of the length L of the channel, so that heat can be spread over the area of the active layers ACT1 that is further increased by the heat spreading patterns ACT1_HS1, ACT_HS2, and damage to the active layers ACT1 due to heat concentrated in a specific portion can be prevented. Moreover, the heat spreading patterns ACT1_HS1, ACT_HS2 are provided at the edges of the active layers ACT1, more effectively dissipating heat to the outside.

In the electrostatic discharge protection device according to an embodiment of the present disclosure, the active layers ACT1 can include an oxide semiconductor. For example, an oxide semiconductor can be formed by binding of at least one metal selected from among indium, gallium, zinc, iron, and tin and an oxide. More specifically, the oxide semiconductor can include at least one selected from among IGZO (indium-gallium-zinc oxide), IGO (indium-gallium oxide), IZO (indium-zinc oxide), FIZO (Fe-indium-zinc oxide), ITO (indium-tin-oxide), TO (tin oxide), and ZO (zinc oxide).

However, the active layers of the electrostatic discharge protection device according to an embodiment of the present disclosure are not necessarily limited to the oxide semiconductor.

The active layers ACT1 of the electrostatic discharge protection device can be formed together with the transistors T1, T2 (FIG. 3) provided in the active area AA (FIG. 1) through the same process. Thus, the active layers of the electrostatic discharge protection device according to an embodiment of the present disclosure can include a crystalline semiconductor layer or an amorphous semiconductor layer by being manufactured together through the same process when the transistors provided in the active area include a crystalline semiconductor layer or an amorphous semiconductor layer.

Here, the inventors of the present disclosure have ascertained that breakdown voltage is increased and thus reliability and stability of the device are improved by forming holes in the active layers and additional heat spreading structures in the electrostatic discharge protection device according to an embodiment of the present disclosure including the active layers made of an oxide semiconductor.

Referring to FIGS. 4 to 6, the cross-sectional configuration of the electrostatic discharge protection device is represented. The electrostatic discharge protection device is provided on a substrate 111.

At least one layer of a first insulating film 121 is provided on the substrate 111 to prevent impurities from being introduced into the device formed on the substrate 111. The first insulating film 121 can function as a buffer.

Further, a first light blocking pattern BB or a second light blocking pattern BA can be provided under the active layers ACT1 on the first insulating film 121.

A second insulating film 122 can be provided on the first light blocking pattern BB and the second light blocking pattern BA to insulate subsequently formed active layers ACT1 from the first light blocking pattern BB or the second light blocking pattern BA.

A third insulating film 123 is provided on the active layers ACT1.

The second electrodes M3, M1 are connected to the active layers ACT1 through first connection holes CTA, CTE, and the third electrodes M1_B, M2_B are connected to the active layers ACT1 through second connection holes CTB, CTF. The third insulating film 123 can be disposed between the active layers ACT1 and the second electrodes M3, M1 and the third electrodes M1_B, M2_B, and thus the first connection holes CTA, CTE and the second connection holes CTB, CTF can be provided in at least the third insulating film 123.

As shown in FIG. 4, the active layers ACT1 can be equally spaced apart from each other for each of the first and second light blocking patterns BB, BA. The first and second light blocking patterns BB, BA are located under the active layers ACT1 and serve to prevent light from entering the active layers ACT1 from below, thereby preventing influence of photocurrent.

For example, depending on the arrangement of the first light blocking pattern BB and the second light blocking pattern BA, electrical signal application of the first electrodes M1_A, M2_A and the third electrodes M1_B, M2_B of the active layers ACT1 differently overlapping the first light blocking pattern BB or the second light blocking pattern BA can vary.

Specifically, for the second electrode M3 overlapping the first light blocking pattern BB, a second electrode extension portion M3E extending to a region that does not overlap the first light blocking pattern BB can be connected to a first power voltage line BC located outside the active layers ACT1 through a third connection hole CTD, and can receive the first power voltage signal applied through the first power voltage line BC. Further, the first electrode M1_A and the third electrode M1_B can be connected to each other through a connecting portion M1_C outside the active layers ACT1, and the connecting portion M1_C can be connected to the first light blocking pattern BB through a fourth connection hole CTC. An external signal caused by static electricity can be input through the first electrode M1_A and the third electrode M1_B.

The metal of the connecting portion M1_C overlapping the first light blocking pattern BB is connected to the first electrode M2_A overlapping the second light blocking pattern BA at the side opposite the second electrode extension portion M3E. The first electrode M1_A, the third electrode M1_B, and the connecting portion M1_C overlapping the first light blocking pattern BB, and the second electrode M1 overlapping the second light blocking pattern BA can be integrally formed and can be branched to left and right based on the connecting portion M1_C.

Similarly, the first electrode M2_A and the third electrode M2_B may be connected to each other through a connecting portion M2_C outside the active layers ACT1, and the connecting portion M2_C may be connected to the second light blocking pattern BA through a fifth connection hole CTG. The third electrode M2_B among the first electrode M2_A, the second electrode M1, and the third electrode M2_B overlapping the second light blocking pattern BA can be connected to the second light blocking pattern BA located outside the active layers ACT1 through a fifth connection hole CTG and can receive a second power voltage signal.

Here, the first power voltage signal is applied through the first power voltage line BC, and the second power voltage signal is applied through a second power voltage line.

Either of the first and second power voltage signals is a VDD signal, and the remaining one is a VSS signal, which means a power voltage signal.

Although the illustrated example does not show external connections of the first and second power voltage lines, connection to power voltage application units through the first and second power voltage lines is possible. The second electrode extension portion BC and the second light blocking pattern BA can be used as a first power voltage signal supply unit and a second power voltage signal supply unit, respectively.

Below, various embodiments of the holes of the electrostatic discharge protection device of the present disclosure are described.

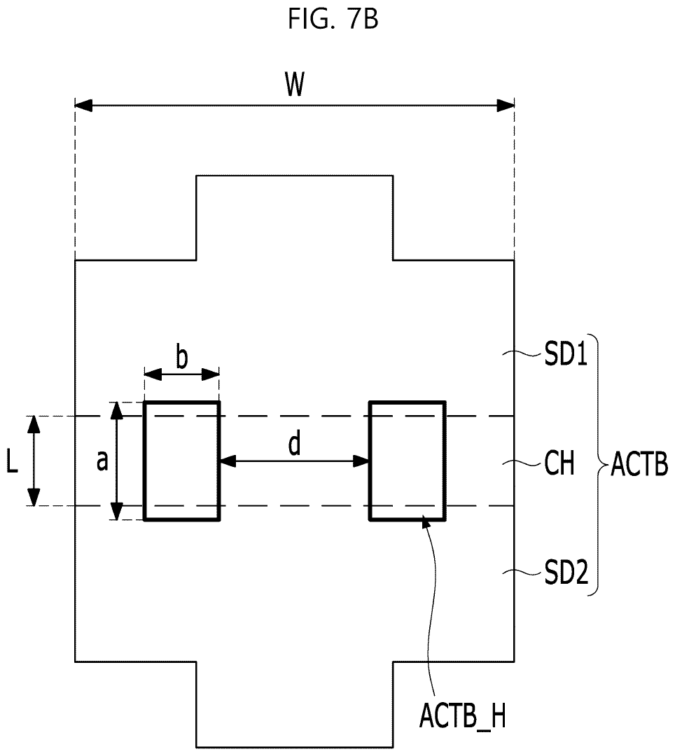

FIGS. 7A to 7D are plan views showing various embodiments of active layers including holes.

As shown in FIG. 4 and FIG. 7A, the active layer ACTA has a channel CH with a first width W in a first direction and a first length L in a second direction intersecting the first direction in the region overlapping the first electrode M1_A (FIG. 4).

The regions excluding the channel CH of the active layer ACTA can be first and second source/drain regions SD1, SD2 that are made conductive by doping with impurities or plasma treatment.

The active layer ACTA can include a first hole ACT1A_HA and a second hole ACTA_HB having different sizes, in which these holes can be spaced apart from each other by a first distance d1 in the first direction. The first hole ACTA_HA can have a first length a greater than the length L of the channel CH in the direction of the length L of the channel CH and a second length ba in the direction of the width W of the channel, and the second hole ACTA_HB can have a first length e equal to or less than the length L of the channel CH in the direction of the length L of the channel CH and a second length bb in the direction of the width W of the channel.

In another embodiment, as shown in FIG. 7B, the active layer ACTB can include holes ACTB_H each having a first length a greater than the length L of the channel CH in the direction of the length L of the channel CH and a second length b in the direction of the width W of the channel, which are spaced apart from each other by a first distance d in the direction of the width W of the channel.

As shown in FIG. 7C, the active layer ACTC can include holes ACTC_H having a first length a1 less than the length L of the channel CH in the direction of the length L of the channel CH and a second length b in the direction of the width W of the channel, which are spaced apart from each other by a first distance d in the direction of the width W of the channel. Here, the holes ACTC_H can be disposed at the boundaries between the channel CH and the source/drain regions SD1, SD2 at complementary positions.

As shown in FIG. 7D, holes ACTD_H having a first length a2 less than the length L of the channel CH in the direction of the length L of the channel CH and a second length b1 in the direction of the width W of the channel can be provided at zigzag positions in the active layer ACTD. The adjacent holes ACTD_H can be spaced apart from each other by a first distance d2 in the direction of the width W.

The holes ACTA_H, ACTB_H, ACTC_H, ACTD_H illustrated in FIGS. 7A to 7D can be distributed in respective active layers ACTA, ACTB, ACTC, ACTD and can function to spread heat when a current path of the channel CH of each of the active layers ACTA, ACTB, ACTC, ACTD is created and to prevent an electric field from being concentrated in a specific area.

The holes of the active layers can be provided at complementary or symmetrical positions with respect to the center of the channel to achieve the heat spreading effect.

In a large-area display device, the electrostatic discharge protection device can require a large area, and accordingly, wide active layers can be provided. Here, the distance between holes in the active layers can be greater than the first length in the width direction of each hole.

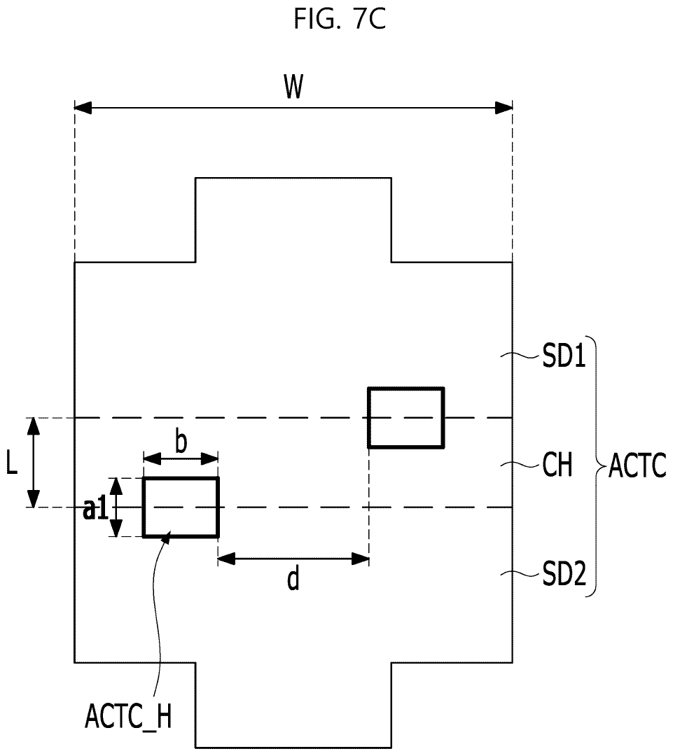

FIG. 8 is a plan view showing an electrostatic discharge protection device according to a second embodiment of the present disclosure.

As shown in FIG. 8, the electrostatic discharge protection device according to the second embodiment of the present disclosure is configured such that heat spreading patterns ACT2_HS1, ACT2_HS2 are provided in multiple branches at the edge of each active layer ACT2 compared to the electrostatic discharge protection device according to the first embodiment described above. Accordingly, each active layer ACT2 exhibits the shape of ‘H’. In addition, the active layers ACT2 have heat spreading patterns ACT2_HS1, ACT2_HS2 at each corner, achieving more effective heat spreading.

The correspondence between the first electrodes M1_A, M2_A, the second electrodes M3, M1, and the third electrodes M1_B, M2_B for the active layers ACT2 is the same as in the first embodiment, so a description thereof is omitted.

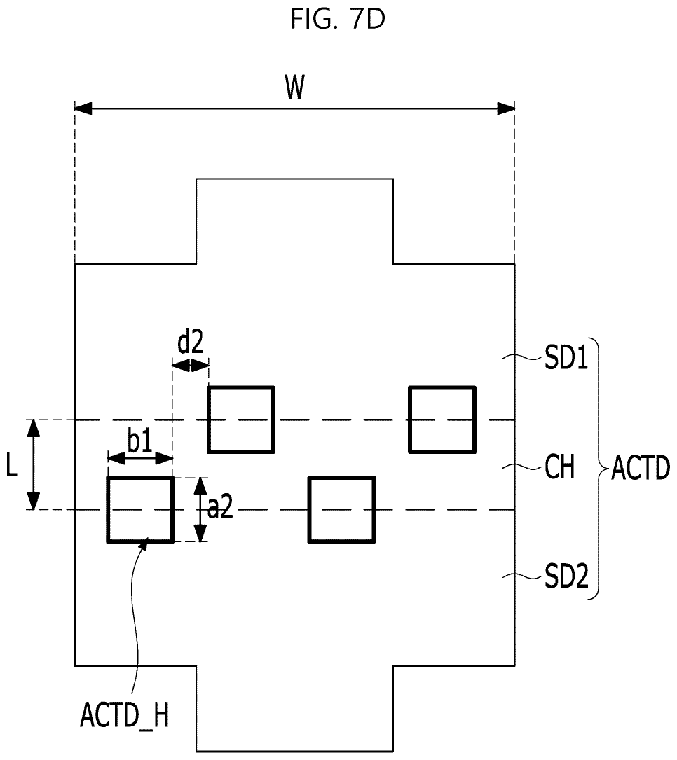

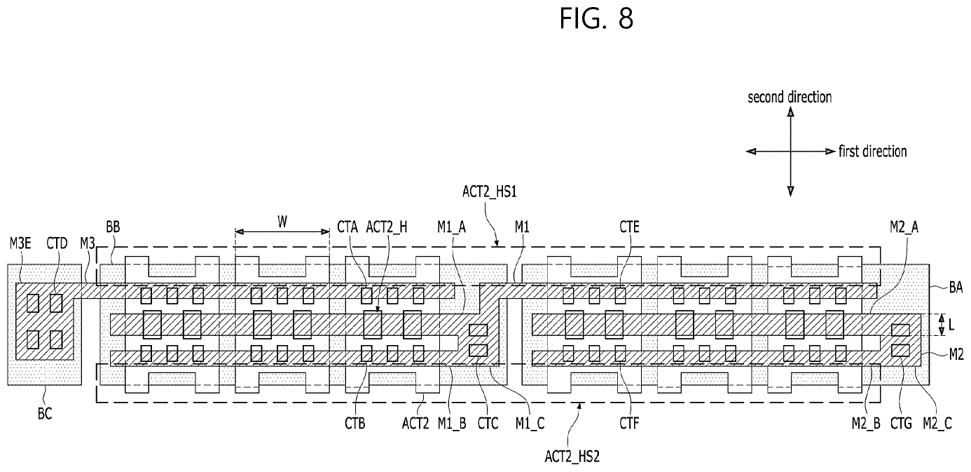

FIG. 9 is a plan view showing an electrostatic discharge protection device according to a third embodiment of the present disclosure, and FIG. 10 is a cross-sectional view along line III-III′ of FIG. 9.

As shown in FIGS. 9 and 10, the electrostatic discharge protection device according to the third embodiment of the present disclosure is configured such that first electrodes SP1, SP2 overlapping each active layer ACT3 are formed to extend not only to the channel CH of the active layer ACT3 but also to a portion of the second source/drain region SD2 and thus have a length GML greater than the length L of the channel in the length direction of the channel. The electrostatic discharge protection device according to the third embodiment is configured such that the first electrodes SP1, SP2 are formed to extend in the length direction of the channel of each active layer ACT3 and are thus integrated with the third electrodes. Therefore, in the electrostatic discharge protection device according to the third embodiment, the third electrodes of each transistor can be omitted from the structure. For example, “a second connection portion” may also be defined as the portion of the first electrodes connected to the active layer at a position opposite to the first connection portion.

The second electrodes M3, M1 and the first electrodes SP1, SP2 are disposed side by side with each other. In the length direction of the channel, the length SDL of the second electrodes M3, M1 can be less than the length CML of the first electrodes SP1, SP2.

As shown in FIGS. 9 and 10, when the first electrode SP1 and the second electrode M3 are disposed on the third insulating film 123, first and second connection holes CTA, CTB are formed in the third insulating film 123 so as to expose portions of the upper surface at both sides of the active layer ACT3, and then the second electrode M3 and the first electrode SP1 are connected to the active layer ACT3 through the first and second connection holes CTA, CTB, respectively.

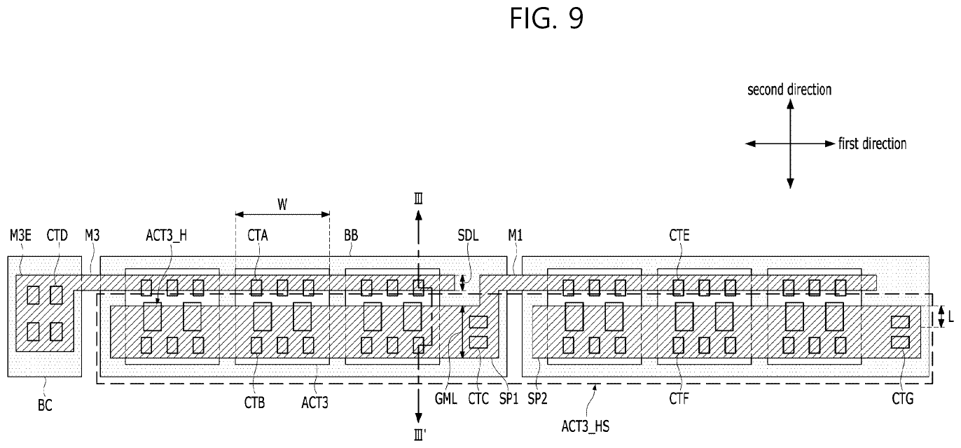

FIG. 11 is a modification of the third embodiment of the present disclosure.

As shown in FIG. 11, the modification of the third embodiment of the present disclosure increases the area of the second connection hole CTBE overlapping each of the first electrodes SP1, SP2 of the active layers ACT3 to utilize the area of the first electrodes SP1, SP2 formed long in the length direction of the channel. Accordingly, the contact area between the active layers ACT3 and the first electrodes SP1, SP2 can increase, and heat generated from the active layers ACT3 can be transferred to the first electrodes SP1, SP2 through the second connection hole CTBE, thereby further enhancing the heat dissipation effect.

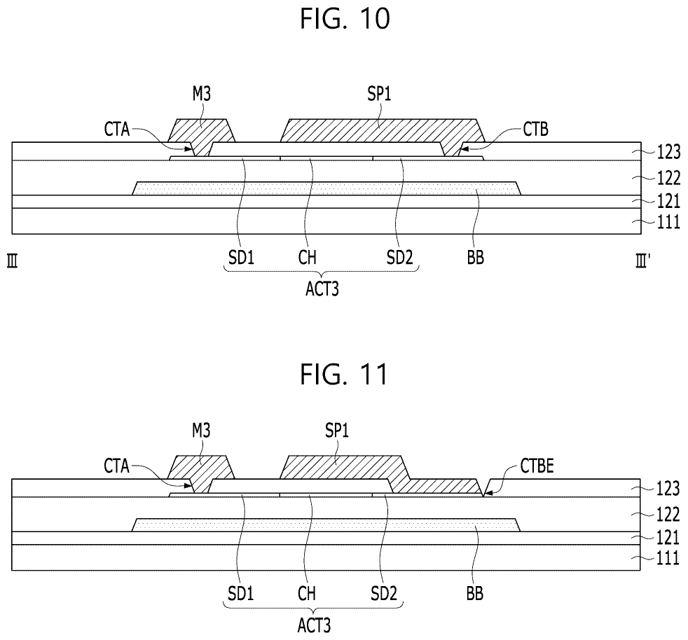

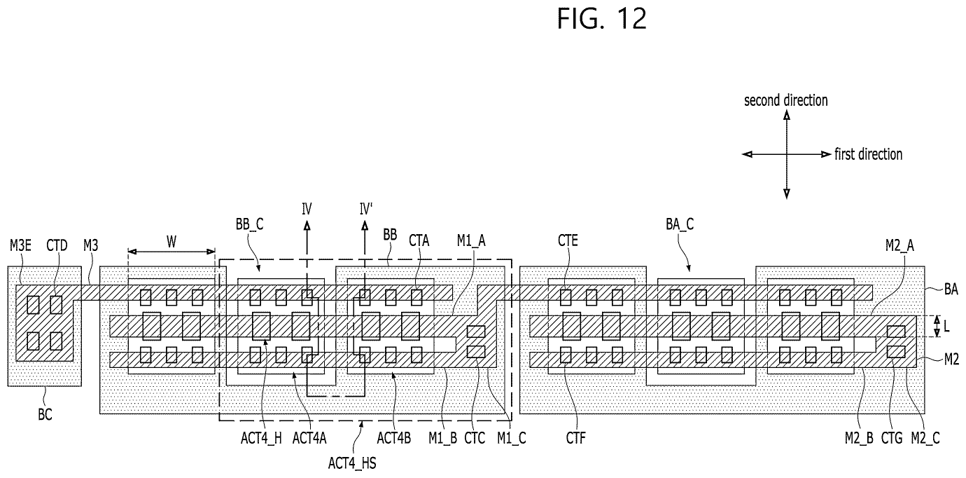

FIG. 12 is a plan view according to a fourth embodiment of the present disclosure, and FIG. 13 is a cross-sectional view along line IV-IV′ of FIG. 12.

As shown in FIGS. 12 and 13, the electrostatic discharge protection device according to the fourth embodiment of the present disclosure is configured such that light blocking patterns BB, BA alternately overlap a plurality of active layers ACT4. Specifically, for example, some portions are removed from the light blocking patterns BB, BA. In this case, the removal portions BB_C, BA_C of the light blocking patterns BB, BA and the light blocking patterns BB, BA are repeatedly disposed, and either of the adjacent active layers ACT4 corresponds to the light blocking patterns BB, BA and the remaining one corresponds to the removal portions BB_C, BA_C of the light blocking patterns. The active layers ACT4 located in the removal portions BB_C, BA_C of the light blocking patterns between the active layers ACT4 overlapping the light blocking patterns BB, BA have a different vertical position between adjacent active layers ACT4 due to step height of the light blocking patterns BB, BA, so that the active layers ACT4 at both sides are spatially separated, preventing heat dissipation from being concentrated in the active layers with the same vertical position.

The previous embodiments of the present disclosure illustrate the first electrodes, the second electrodes, and the third electrodes, which are located on the same layer. However, the embodiments of the present disclosure are not limited thereto.

Below, an embodiment of the present disclosure in which the first electrodes, the second electrodes, and the third electrodes are located on different layers is described.

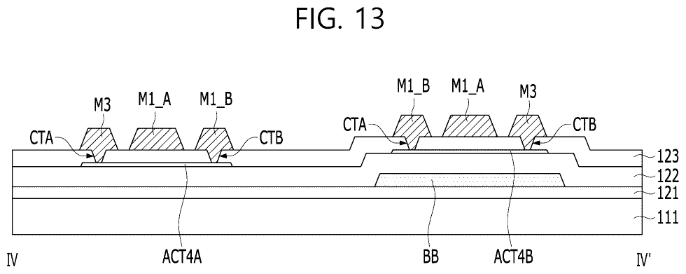

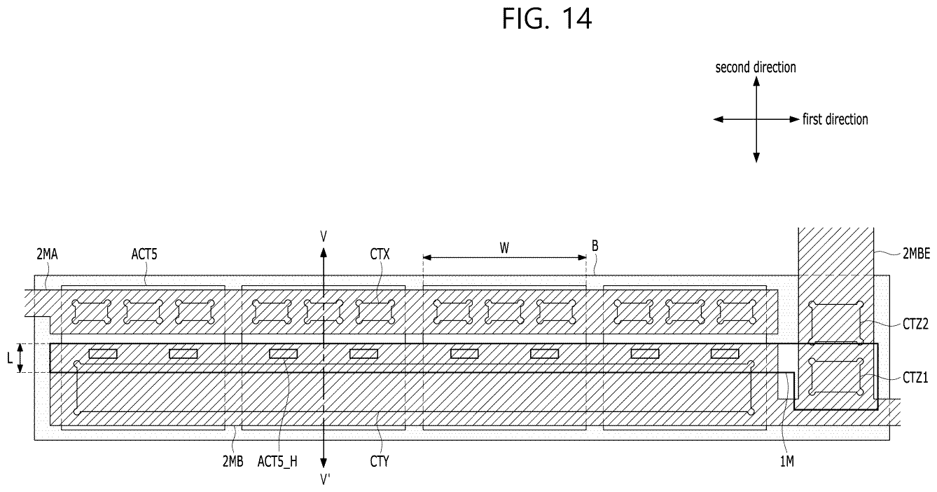

FIG. 14 is a plan view according to a fifth embodiment of the present disclosure, and FIG. 15 is a cross-sectional view along line V-V′ of FIG. 14.

As shown in FIGS. 14 and 15, the electrostatic discharge protection device according to the fifth embodiment of the present disclosure includes a first electrode 1M disposed long in a first direction (arrow direction of W).

Further, the electrostatic discharge protection device includes active layers ACT5, each of which has a first width W in the first direction, overlaps the first electrode 1M, includes at least one hole ACT5_H in the overlapping region, and is disposed longer outwardly than both sides of the first electrode 1M in a second direction (arrow direction of V-V′) intersecting the first direction.

In addition, the electrostatic discharge protection device can include a second electrode 2MA and connected to one side of the active layers ACT5 and a third electrode 2MB connected to the remaining side of the active layers ACT5, disposed side by side with the first electrode 1M.

The active layers ACT5 each having a first width W can be spaced apart from each other in the first direction.

Each of the active layers ACT5 can overlap the first electrode 1M by a first length L in the second direction intersecting the first direction, can have a channel region with a first width W and a first length L, and can have source/drain regions at both sides of the channel region in the second direction.

In the electrostatic discharge protection device according to the fifth embodiment of FIGS. 14 and 15, a transistor in which the first electrode 1M is used as a gate electrode and the second electrode 2MA and the third electrode 2MB at both sides are used as respective first and second source/drain electrodes is provided corresponding to each active layer ACT5.

The second electrode 2MA is connected to the active layer ACT5 through a first connection hole CTX.

The third electrode 2MB is provided to overlap the first electrode 1M, the third electrode 2MB is connected to the active layer ACT5 through a second connection hole CTX, and the second connection hole CTY exposing a portion of the upper surface of the active layer ACT5 is formed to be larger than the first connection hole CTX so that a side of the first electrode 1M is exposed, whereby the third electrode 2MB is connected to both the first electrode 1M and the active layer ACT5 through the second connection hole CTY.

Therefore, in the electrostatic discharge protection device according to the fifth embodiment, heat in the active layer ACT5 can be transferred together to the metal layers of the third electrode 2MB and the first electrode 1M connected through the second connection hole CTY, thereby further improving the heat dissipation effect.

Further, the first electrode 1M of each transistor can have the same node by being electrically connected to the third electrode 2MB. This configuration is the same as the configuration of each transistor of FIG. 3 in which the gate electrode and the source electrode are connected.

Meanwhile, the active layer ACT5 includes at least one hole ACT5_H in a region overlapping the first electrode 1M. Here, the hole functions to spread heat generated from each transistor and spread an electric field around the hole.

As shown in FIGS. 14 and 15, the electrostatic discharge protection device is provided on a substrate 111.

At least one layer of a first insulating film 211 is provided on the substrate 111 to prevent impurities from being introduced into the device formed on the substrate 111. The first insulating film 221 can function as a buffer.

Further, a light blocking pattern B can be provided under the active layer ACT5 on the first insulating film 221.

A second insulating film 222 is provided on the light blocking pattern B to insulate subsequently formed active layers ACT5 from the light blocking pattern B.

A plurality of active layers ACT5 can be provided on the second insulating film 222. The active layers ACT5 can each have a first width W and can be disposed in the first direction.

A third insulating film 223 and a first electrode 1M can be disposed across the center of each active layer ACT5 in the direction of the width W of the active layers ACT5. The third insulating film 223 and the first electrode 1M can be formed through the same patterning process and can be provided at a position corresponding to the channel of the active layer ACT5. Accordingly, the first electrode 1M can have a first length L in a direction intersecting the width direction of the active layer ACT5.

A fourth insulating film 224 is provided on the active layer ACT5, and a first connection hole CTX and a second connection hole CTY are provided to expose both sides of the active layer ACT5 by selectively removing the fourth insulating film 224. Here, the second connection hole CTY can be formed to be larger than the first connection hole CTX in both the width direction of the channel and the length direction intersecting the width.

The second electrode 2MA is connected to the active layer ACT5 through the first connection hole CTX, and the third electrode 2MB overlaps and is connected to the first electrode 1M at the portion of the upper surface and the side of the first electrode 1M exposed and is connected to the active layer ACT5 at the lower surface thereof through the second connection hole CTY. Therefore, heat generated from the active layer ACT5 can be spread to the first electrode 1M and the third electrode 2MB located on different layers, thereby achieving a higher heat dissipation effect.

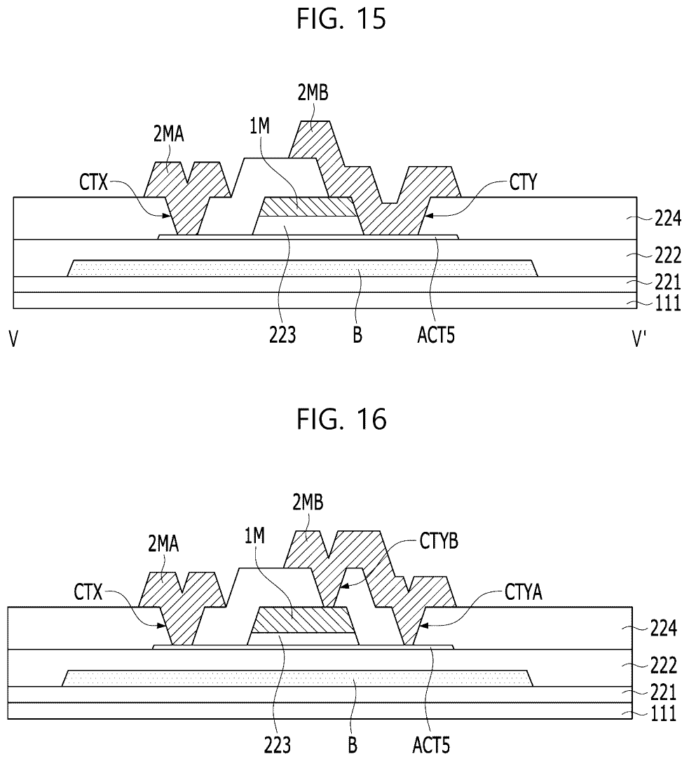

FIG. 16 is a modification of the fifth embodiment of the present disclosure.

As shown in FIG. 16, the modification of the fifth embodiment of the present disclosure includes not only a first hole CTX and a second hole CTYA exposing portions of the upper surface at both sides of the active layer ACT5 in the fourth insulating film 224 but also a third hole CTYB exposing a portion of the upper surface of the first electrode (functioning as a gate electrode) 1M so that the third electrode 2MB is connected to two positions on the first electrode 1M and the active layer ACT5.

By placing the third electrode 2MB in both the second hole CTYA and the third hole CTYB, similar to the fifth embodiment described above, heat generated from the active layer ACT5 can be spread to the first electrode 1M and the third electrode 2MB located on different layers, thereby achieving a higher heat dissipation effect.

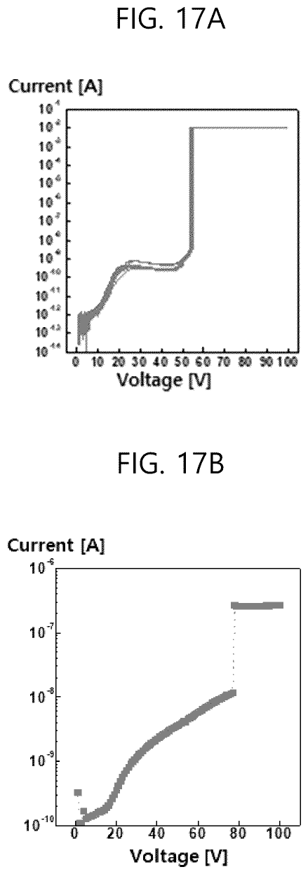

FIG. 17A is graphs showing results of evaluation of breakdown voltage of an electrostatic discharge protection circuit without heat dissipation means. FIG. 17B is a graph showing results of evaluation of breakdown voltage of the electrostatic discharge protection circuit according to an embodiment of the present disclosure.

As shown in FIG. 17A, the electrostatic discharge protection circuit without holes in the active layers or heat spreading patterns has an average breakdown voltage (BV) of 54 V, but as shown in FIG. 17B, in a structure having holes in the active layers and heat spreading patterns or multiple heat spreading paths as in the embodiments of the present disclosure, the breakdown voltage is determined to be 78 V or higher.

The electrostatic discharge protection circuit according to embodiments of the present disclosure can exhibit good reliability and pattern stability.

Below, a display device according to one or more embodiments of the present disclosure is described.

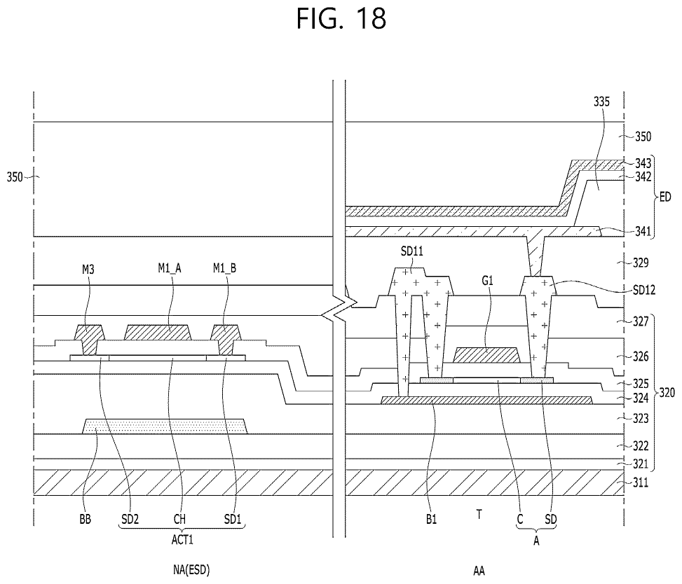

FIG. 18 is a cross-sectional view showing a display device according to an embodiment of the present disclosure.

As shown in FIG. 18, a substrate 311 can be formed of a flexible plastic material and thus can have flexibility. For example, the substrate 311 can be formed of first and second organic films overlapping each other with an inorganic interlayer insulating film therebetween. The first and second organic films can include different organic films of the same or different types, such as PET (polyethylene terephthalate), polyimide, etc. In some cases, an adhesive film such as a pressure sensitive adhesive (PSA) can be disposed between the first and second organic films.

As another example, the substrate 311 can include a thin glass material having flexibility.

The substrate 311 serves to support and protect the components of the display device 100 disposed thereon.

In addition to the first and second transistors T1, T2 described in FIG. 2, various types of transistors included in the compensation circuit CC can be provided in the active area AA of the substrate 311. FIG. 18 illustrates a driving transistor T connected to a light emitting device ED.

The electrostatic discharge protection device ESD as described in FIGS. 3 to 16 can be provided in the non-active area NA of the substrate 311.

A plurality of stacked insulating films 320:321, 322, 323, 324, 325, 326, 327 can be disposed on the active area AA and the non-active area NA (FIG. 1) of the substrate 311, so that the first light blocking pattern BB, the third light blocking pattern B1, and the electrodes G1, SD11/SD12 and the electrodes M1_A/M3/M1_B constituting the first and second transistors T1, T2 can be insulated from each other. The insulating films 320 can include a first insulating film 321, a second insulating film 322, a third insulating film 323, a fourth insulating film 324, a fifth insulating film 325, a sixth insulating film 326, and a seventh insulating film 327.

The first insulating film 321 is disposed on the active area AA and the non-active area NA on the substrate 311. The first insulating film 321 can be referred to as a buffer layer and can have the same function as a buffer layer known in the art. The first insulating film 321 can be disposed on the substrate 311 to protect structures located on the substrate 311 from water penetrating through the substrate 311 and to achieve surface planarization of the substrate 311.

The first insulating film 321 is disposed up to the edge of the substrate 311 to prevent water from penetrating from the edge of the substrate 311. The first insulating film 321 can be a single inorganic film or can be composed of multiple inorganic films that are alternately stacked.

For example, the first insulating film 321 can include at least one inorganic film selected from among a silicon oxide (SiOx) film, a silicon nitride (SiNx) film, and a silicon oxynitride (SiOxNy) film, or can include a multilayer film in which the inorganic films described above are stacked.

The second insulating film 322 can be disposed on the first insulating film 321. The second insulating film 322 can function as, for example, a second buffer layer. As such, some of the transistors included in the sub-pixels can include a polysilicon semiconductor layer, and the second insulating film 322 can be located under the polysilicon semiconductor layer. The second insulating film 322 can include an inorganic film, for example, a silicon oxide (SiOx) film, a silicon nitride (SiNx) film, or a multilayer film thereof. In some cases, the second insulating film 322 can be used as a gate insulating film of a transistor including a polysilicon semiconductor layer.

A first light blocking pattern BB can be provided using a conductive metal material on the second insulating film 322. Specifically, the conductive metal material can include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first light blocking pattern BB can extend to form any one electrode of a capacitor included in a driver of a non-active area or a sub-pixel.

The third insulating film 323 can be disposed on the second insulating film 322 with the first light blocking pattern BB formed thereon. The third insulating film 323 can function as an insulator of a capacitor included in the driver of the non-active area NA and the active area AA. Alternatively, the third insulating film 323 can function as an interlayer insulating film of a transistor including a polysilicon semiconductor layer.

The third insulating film 323 can include an inorganic material. The inorganic material can include, for example, a silicon nitride (SiNx) film.

A third light blocking pattern B1 is disposed on the third insulating film 323 using a conductive metal material. Specifically, the conductive metal material can include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first and third light blocking patterns BB, B1 can be located on the same layer as the first and second electrodes of the capacitor, respectively. The first and third light blocking patterns BB, B1 can have a monolayer structure or a stack structure of multiple different metal materials.

The fourth insulating film 324 can be disposed on the third insulating film 323 with the third light blocking pattern B1 formed thereon. The fourth insulating film 324 is located beneath the first and second active layers ACT1, A, and can function as a buffer layer. The fourth insulating film 324 can serve to achieve surface planarization of the area where the first and second active layers ACT1, A disposed thereon are formed.

The fourth insulating film 324 can include an inorganic material. The inorganic material can include, for example, a silicon oxide (SiOx) film or a multilayer film of stacked inorganic films.

The first and second active layers ACT1, A are disposed on the fourth insulating film 324. The first and second active layers ACT1, A include, for example, an oxide semiconductor material. The oxide semiconductor material can be formed of a combination of at least one metal selected from among zinc (Zn), indium (In), gallium (Ga), tin (Sn), and titanium (Ti) and an oxide. In some cases, mobility can be increased by further adding a highly conductive metal, such as iron (Fe), to the oxide semiconductor material.

More specifically, examples of the oxide semiconductor material constituting the first and second active layers ACT1, A can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), Fe-indium-zinc oxide (FIZO), and the like.

The fifth insulating film 325 is disposed to cover the first active layer ACT1 and the second active layer A. The fifth insulating film 325 can function as a gate insulating film for the electrostatic discharge protection device and the transistor T.

Each of the first active layers ACT1 can have a channel CH in the central region and source/drain regions SD1, SD2 at both sides of the channel. Each of the second active layers A can have a channel C in the central region and source/drain regions SD at both sides of the channel. Further, as described in FIGS. 4 to 16, the first active layer ACT1 can include at least one hole ACT1_H in a region overlapping the first electrode M1_A to spread heat and an electric field when a high current or high voltage signal due to static electricity is applied. The first active layer ACT1 can also have heat spreading patterns at both sides in the length direction intersecting the width direction, thus enhancing the heat dissipation effect.

In the non-active area NA, a first electrode M1_A overlapping the channel CH of the first active layer ACT1 with the fifth insulating film 325 therebetween is disposed on the fifth insulating film 325, and a second electrode M3 and a third electrode M1_B connected to the first active layer ACT1 through contact holes provided in the fifth insulating film 325 are disposed. The first electrode M1_A and the third electrode M1_B can be electrically connected to each other.

In addition, as shown in FIG. 4, the extension portion of the first electrode M1_A or the third electrode M1_B can be connected to the first light blocking pattern BB in a region not overlapping the first active layer ACT1, so that the same signal can be applied.

Further, a gate electrode G1 partially overlapping the second active layer A with the fifth insulating film 325 therebetween is disposed on the fifth insulating film 325 of the active area AA.

The gate electrode G1 and the first electrode M1_A, the second electrode M3, and the third electrode M1_B can include at least one selected from among an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The gate electrode G1 and the first to third electrodes M1_A, M3, M1_B can be formed of a single layer or multiple layers.

The sixth insulating film 326 and the seventh insulating film 327 are disposed on the fifth insulating film 325 on which the first to third electrodes M1_A, M3, M1_B and the gate electrode G1 are disposed.

The first to seventh insulating films 321, 322, 323, 324, 325, 326, 327 described above are formed of an inorganic insulating material and can include, in some cases, a single layer or multiple layers. For example, the first to seventh insulating films 321, 322, 323, 324, 325, 326, 327 can include a silicon oxide (SiOx) film, a silicon nitride (SiNx) film, or a silicon oxynitride (SiOxNy) film.

When the first active layer ACT1 and the second active layer A include an oxide semiconductor, the fifth insulating film 325 and the sixth insulating film 326 adjacent to the first and second active layers ACT1, A can be formed of a silicon oxide film to prevent hydrogen influence on the oxide semiconductor.

The second active layer A is connected to the first source/drain electrode SD11 and the second source/drain electrode SD12 through a contact hole in which the source/drain regions SD of the second active layer A is exposed by selectively removing the seventh insulating film 327, the sixth insulating film 326, and the fifth insulating film 325. Through the same process of forming the contact hole exposing the second active layer A, the fourth insulating film 324 is further etched to expose a portion of the upper surface of the third light blocking pattern B1 that further extends than one side of the second active layer A, thereby providing a connection portion between the third light blocking pattern B1 and the first source/drain electrode SD11. Thereby, the third light blocking pattern B1 can have the same potential as the first source/drain electrode SD11 and can thus be electrically stabilized.

The first and second source/drain electrodes SD11, SD12 can include at least one selected from among an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

A planarization layer 329 configured to protect the electrostatic discharge protection device ESD and the transistor T can be provided on the first and second source/drain electrodes SD11, SD12.

The planarization layer 329 can include an organic material. The organic material can include at least one selected from among an acrylic resin, a phenolic resin, a polyimide resin, an unsaturated polyester resin, a polyamide resin, benzocyclobutene, a polyphenylene resin, and a polyphenylene sulfide resin.

An anode 341 can be further provided on the planarization layer 329 and can be connected to, for example, the second source/drain electrodes SD12 through a contact hole in the planarization layer 329.

The anode 341, a cathode 343 opposite thereto, and an intermediate layer 342 between the anode 341 and the cathode 343 form a light emitting device ED.

Either the anode 341 or the cathode 343 can include a reflective electrode, and the remaining one can include a transparent electrode or a reflective transparent electrode.

When the anode 341 includes a reflective electrode, the anode 341 can function to shield light from being incident on the transistor T at a lower position. The anode 341 can be formed of, for example, a stack structure of a first transparent electrode, a reflective electrode, and a second transparent electrode. The second transparent electrode, which is the uppermost electrode of the anode 341, can reduce the barrier for hole injection at the interface with the intermediate layer 342 as a dielectric. Here, the first and second transparent electrodes can be transparent oxide electrodes formed of ITO, IZO, etc. The reflective electrode can include silver, a silver alloy such as APC (Ag—Pd—Cu), aluminum, or an aluminum alloy.

For example, the anode 341 can have a multilayer structure such as a stack structure of aluminum (Al) and titanium (Ti) (Ti/Al/Ti), a stack structure of aluminum (Al) and ITO (ITO/AI/ITO), an APC (Ag/Pd/Cu) alloy, a stack structure of an APC alloy and ITO (ITO/APC/ITO), or a stack structure of silver (Ag) and molybdenum/titanium alloy (Ag/MoTi), or can include a monolayer structure made of any one material selected from among silver (Ag), aluminum (Al), molybdenum (Mo), gold (Au), magnesium (Mg), calcium (Ca), and barium BA, or an alloy material of two or more thereof.

A pixel definition layer 335 can be disposed surrounding the edge of the anode 341, and an emissive portion can be defined in an open region of the pixel definition layer.

The pixel definition layer 335 can include an inorganic material or an organic material. The pixel definition layer 335 can also include an opaque material (e.g., black) to prevent optical interference between adjacent sub-pixels SP. As such, the pixel definition layer 335 can include a light blocking material including at least one selected from among a color pigment, organic black, and carbon.

The intermediate layer 342 can include a hole injection layer, a hole transport layer, an emission layer, an electron transport layer, and an electron injection layer. The intermediate layer 342 can be composed of a plurality of stacks including a hole transport layer, an emission layer, and an electron transport layer, and can also be formed in a tandem structure including a charge generation layer between the stacks. The charge generation layer can include, for example, an n-type charge generation layer and a p-type charge generation layer.

The emission layer included in the intermediate layer 342 can be provided differently for each sub-pixel. The emission layer EL can be composed of a red emission layer that emits red light, a green emission layer that emits green light, and a blue emission layer that emits blue light. The red emission layer, the green emission layer, and the blue emission layer can be disposed for respective sub-pixels SP on the anode 341.

For example, a red emission layer can be patterned and disposed in a red sub-pixel, a green emission layer can be patterned and disposed in a green sub-pixel, and a blue emission layer can be patterned and disposed in a blue sub-pixel. The present disclosure is not necessarily limited thereto, and at least two organic emission layers selected from among a red emission layer, a green emission layer, and a blue emission layer can be stacked and disposed in one sub-pixel SP.

The emission layer EL can be a white emission layer that emits white light. As such, the emission layer EL can be in the form of a common layer in which one or more layers are commonly disposed in the sub-pixels SP, rather than in a patterned form.

As described above, the emission layer EL can be disposed in a tandem structure of two or more stacks. As such, each light emitting device ED can include a charge generation layer disposed between the stacks. The charge generation layer can be a common layer disposed on the front surface of the active area AA.

The cathode 343 can be formed by thinning a transparent electrode such as ITO, IZO, etc., or a reflective transparent electrode such as silver, a silver alloy, magnesium, a magnesium alloy, ytterbium (Yb), an ytterbium alloy, etc. In another embodiment, the cathode 343 can be formed at a low thickness or by partial removal from a transmissive portion to increase transmittance in a transmissive portion. The cathode 343 can be a common layer that is commonly disposed in the sub-pixels SP and applies the same voltage. To this end, the cathode 343 can be formed to extend from the active area AA to a portion of the non-active area NA.

The cathode 343 can be a transparent electrode. The cathode 343 can include a transparent conductive material (TCO) such as ITO or IZO capable of transmitting light, or a semi-transmissive conductive material such as magnesium (Mg), silver (Ag), or an alloy of magnesium (Mg) and silver (Ag). When the cathode 343 is provided using a semi-transmissive conductive material, light extraction efficiency can be increased by virtue of microcavity design.

The top emission-type light emitting device ED was described above. However, the light emitting device ED of the present disclosure is not limited thereto, and can be provided in a bottom emission type in which light emitted from the intermediate layer 342 is emitted toward the substrate 311. As such, the anode 341 can be composed of a transparent or translucent electrode material, and the cathode 343 can be composed of a reflective electrode material.

An encapsulation layer 350 is disposed on the light emitting device ED. The encapsulation layer 350 can serve to cover the active area AA and the non-active area NA to prevent oxygen or water from penetrating the light emitting device ED. Other layers, such as a capping layer, etc., can be interposed between the encapsulation layer 350 and the cathode 343 as necessary.

The encapsulation layer 350 can be composed of multiple layers. The encapsulation layer 350 can be configured such that an inorganic film including an inorganic insulating material and an organic film including an organic insulating material are alternately stacked. For example, the inorganic insulating material can include at least one selected from among silicon oxide, silicon nitride, and silicon oxynitride.

The organic insulating material can include at least one selected from the group consisting of polyethylene terephthalate, polyethylene naphthalate, polycarbonate, polyimide, polyethylene sulfonate, polyoxymethylene, polyarylate, and hexamethyldisiloxane.

A capping layer is further formed on the cathode 343 to protect the cathode 343 of the light emitting device ED and increase light extraction efficiency upward.

In embodiments of the present disclosure, an electrostatic discharge protection device ESD provided in a non-active area NA can be manufactured together with a driving transistor T2 (FIG. 2) or a switching transistor T1 (FIG. 2) provided in an active area AA including an oxide semiconductor. Therefore, the electrostatic discharge protection device can be formed together with the transistors in the active area AA without any additional process, and process optimization is possible.

Further, in a display device according to embodiments of the present disclosure, when an oxide semiconductor having high mobility is included in the transistors T1, T2 in the active area AA, holes and heat spreading patterns are provided to active layers of the electrostatic discharge protection device formed together with the active layers of the transistors T1, T2, thereby improving reliability of the electrostatic discharge protection device having high Joule heating load due to high mobility, and enhancing operational stability.

The electrostatic discharge protection device according to an embodiment of the present disclosure can prevent heat generated from the active layers from being concentrated in a specific area and adjust an electric field by forming holes in the active layers.

The electrostatic discharge protection device according to an embodiment of the present disclosure further include heat spreading patterns at edges of the active layers, thus spreading heat generated from the active layers and easily dissipating heat to the outside.

In the electrostatic discharge protection device including a high-mobility oxide semiconductor, holes and heat spreading patterns for heat dissipation of the active layers are provided, so that heat spreading and heat dissipation of the active layers are possible by heat dissipation through multilayer metal, increasing breakdown voltage of the electrostatic discharge protection device and improving reliability thereof. If the electrostatic discharge protection device including a high-mobility oxide semiconductor does not have holes or heat spreading patterns for heat dissipation, heating can be aggravated and, in severe cases, the electrostatic discharge protection device can explode. The electrostatic discharge protection device according to embodiments of the present disclosure is capable of solving such problems.

The electrostatic discharge protection device according to an embodiment of the present disclosure can be manufactured through the same process as the transistors of the active area, and enables addition of a heat dissipation path by forming a pattern of an active layer or a contact hole between an electrode layer and an active layer without any additional process, thereby preventing a change in a conductive area due to heat concentration in a channel without harmful gases or additional materials and improving breakdown voltage. Thus, greenhouse gas emissions can be reduced.

The display device including the electrostatic discharge protection device according to an embodiment of the present disclosure can improve durability of the electrostatic discharge protection device and stabilize a signal input via the electrostatic discharge protection device, thereby improving operational stability of the display device.

Moreover, the electrostatic discharge protection device according to an embodiment of the present disclosure is configured to prevent conductive diffusion that is aggravated by heat when applied to a transistor having a wide channel, solving problems of threshold voltage sensitivity in wide devices due to a change in channel length caused by conductive diffusion. Therefore, the electrostatic discharge protection device according to an embodiment of the present disclosure can improve reliability of the transistor by controlling a change in effective channel length of the transistor including the oxide semiconductor.

The electrostatic discharge protection device according to an embodiment of the present disclosure can prevent or reduce a change in the effective channel length even when having a wide channel, thus preventing or reducing a change in threshold voltage. Therefore, when forming a wide channel transistor, the channel length margin can be minimized, enabling operation at low power compared to a structure with a channel length margin.

The display device according to an embodiment of the present disclosure can be configured such that a wide channel transistor having device stability is included in an active area or a non-active area.

The display device according to an embodiment of the present disclosure has a high degree of design freedom by reducing threshold voltage sensitivity depending on a change in channel width, thus achieving a narrow bezel by disposing a high-output transistor in a small size in a non-active area.

The display device according to an embodiment of the present disclosure is capable of controlling the change in effective channel length in a wide channel transistor and reducing threshold voltage sensitivity, enabling the application of a high-output wide channel transistor in a small size, thereby reducing power consumption and achieving operation at low power, and thus has the advantage of being environmentally and socially sustainable. Therefore, ESG (environmental/social/governance) goals can be achieved.

An electrostatic discharge protection device according to one embodiment of the present disclosure can comprise a first electrode disposed long in a first direction, an active layer, which has a first width in the first direction, overlaps the first electrode, comprises at least one hole in an overlapping region, and is disposed longer outwardly than both sides of the first electrode in a second direction intersecting the first direction and a second electrode parallel to the first electrode and having a first connection portion to one end of the active layer.

In an electrostatic discharge protection device according to one embodiment of the present disclosure, the active layer can have at least one heat spreading pattern protruding outwardly in the second direction.

In an electrostatic discharge protection device according to one embodiment of the present disclosure, the active layer can comprise a plurality of active layer patterns spaced apart from each other in the first direction, each of the active layer patterns overlapping the first electrode and the second electrode.

An electrostatic discharge protection device according to one embodiment of the present disclosure can further comprise a third electrode having a second connection portion to the active layer at a position opposite to the first connection portion with the first electrode therebetween.

In an electrostatic discharge protection device according to one embodiment of the present disclosure, the first electrode and the third electrode can be connected to each other.

In an electrostatic discharge protection device according to one embodiment of the present disclosure, the first electrode and the third electrode can be connected at a region not overlapping the active layer.

In an electrostatic discharge protection device according to one embodiment of the present disclosure, the first electrode can be located at a different layer from the second electrode and the third electrode, and the third electrode overlaps the first electrode.

In an electrostatic discharge protection device according to one embodiment of the present disclosure, the first electrode can have a second connection portion to the active layer at a position opposite to the first connection portion.

An electrostatic discharge protection device according to one embodiment of the present disclosure can further comprise a light blocking pattern overlapping at least one of the plurality of active layer patterns under the active layer.

In an electrostatic discharge protection device according to one embodiment of the present disclosure, the light blocking pattern can integrally overlap the plurality of active layer patterns.

In an electrostatic discharge protection device according to one embodiment of the present disclosure, the light blocking pattern can alternately overlap the active layer patterns.

In an electrostatic discharge protection device according to one embodiment of the present disclosure, the at least one hole can be distributed in a region overlapping the first electrode and a region not overlapping the first electrode in the active layer.

In an electrostatic discharge protection device according to one embodiment of the present disclosure, the active layer can comprise an oxide semiconductor.

In an electrostatic discharge protection device according to one embodiment of the present disclosure, an external signal can be applied to the first electrode and a power voltage is applied to the second electrode.

In an electrostatic discharge protection device according to one embodiment of the present disclosure, the first electrode and the second electrode can be located at a same layer.

A display device according to one embodiment of the present disclosure can comprise a substrate comprising an active area comprising a plurality of sub-pixels and a non-active area surrounding the active area and the above electrostatic discharge protection device provided at the non-active area.

In a display device according to one embodiment of the present disclosure, the substrate can comprise a pad portion and a gate-in-panel at the non-active area, and the electrostatic discharge protection device is provided between the pad portion and the gate-in-panel.

A display device can further comprise a line-on-glass block between the pad portion and the gate-in-panel.

In a display device according to one embodiment of the present disclosure, each of the sub-pixels can comprise a transistor comprising an oxide semiconductor.

As is apparent from the foregoing, an electrostatic discharge protection device according to an embodiment of the present disclosure is capable of preventing heat generated from an active layer from being concentrated in a specific area and adjusting an electric field by providing a hole in the active layer.

The electrostatic discharge protection device according to an embodiment of the present disclosure is capable of spreading heat generated from the active layer and easily dissipating heat to the outside by further providing a heat spreading pattern at an edge of the active layer.

In the electrostatic discharge protection device including a high-mobility oxide semiconductor, a hole and a heat spreading pattern for heat dissipation of the active layer are provided, enabling heat spreading and heat dissipation of the active layer by heat dissipation through multilayer metal, and also increasing breakdown voltage of the electrostatic discharge protection device and improving reliability thereof.

The electrostatic discharge protection device according to an embodiment of the present disclosure can be manufactured through the same process as transistors of an active area, and enables addition of a heat dissipation path by forming a pattern of an active layer or a contact hole between an electrode layer and an active layer without any additional process, thereby preventing a change in a conductive area due to heat concentration in a channel without harmful gases or additional materials and improving breakdown voltage. Therefore, greenhouse gas emissions can be prevented.

A display device including the electrostatic discharge protection device according to an embodiment of the present disclosure can improve durability of the electrostatic discharge protection device and stabilize a signal input via the electrostatic discharge protection device, thereby improving operational stability of the display device.

In addition, the electrostatic discharge protection device according to an embodiment of the present disclosure is configured to prevent conductive diffusion that is aggravated by heat when applied to a transistor having a wide channel, thus solving problems of threshold voltage sensitivity in wide devices due to the channel length change caused by conductive diffusion. Therefore, the electrostatic discharge protection device according to an embodiment of the present disclosure can improve reliability of the transistor by controlling a change in the effective channel length of the transistor including the oxide semiconductor.

The electrostatic discharge protection device according to an embodiment of the present disclosure can prevent or reduce a change in an effective channel length even when having a wide channel, thus preventing or reducing a change in threshold voltage. Therefore, when forming a wide channel transistor, the channel length margin can be minimized, enabling operation at low power compared to a structure with a channel length margin.

The display device according to an embodiment of the present disclosure is configured such that a wide channel transistor having device stability is included in an active area or a non-active area.

The display device according to an embodiment of the present disclosure has a high degree of design freedom by reducing threshold voltage sensitivity depending on a change in channel width, thus achieving a narrow bezel by disposing a high-output transistor in a small size in a non-active area.

The display device according to an embodiment of the present disclosure is capable of controlling the change in effective channel length in a wide channel transistor and reducing threshold voltage sensitivity, enabling the application of a high-output wide channel transistor in a small size, thereby reducing power consumption and achieving operation at low power, and thus has the advantage of being environmentally and socially sustainable. Therefore, ESG (environmental/social/governance) goals can be achieved.

Those skilled in the art will understand that various modification and alternations are possible from the above description without departing from the technical idea of the present disclosure. Consequently, the technical scope of the present disclosure is defined by the appended claims, not by the detailed description of the present disclosure.

What is claimed is:

1. An electrostatic discharge protection device, comprising:
a first electrode extending in a first direction;
an active layer having a first width in the first direction, and configured to overlap the first electrode,
wherein the active layer comprises at least one hole in an overlapping region with the first electrode, and
wherein the active layer is disposed longer outwardly than some sides of the first electrode in a second direction intersecting the first direction; and
a second electrode disposed parallel to the first electrode and having a first connection portion connected to one end of the active layer.

2. The electrostatic discharge protection device according to claim 1, wherein the active layer has at least one heat spreading pattern protruding outwardly in the second direction.

3. The electrostatic discharge protection device according to claim 1, wherein the active layer comprises a plurality of active layer patterns spaced apart from each other in the first direction, each of the plurality of active layer patterns overlapping the first electrode and the second electrode.

4. The electrostatic discharge protection device according to claim 1, further comprising a third electrode having a second connection portion connected to the active layer at a position opposite to the first connection portion with the first electrode therebetween.

5. The electrostatic discharge protection device according to claim 4, wherein the first electrode and the third electrode are connected to each other.

6. The electrostatic discharge protection device according to claim 5, wherein the first electrode and the third electrode are connected at a region not overlapping the active layer.

7. The electrostatic discharge protection device according to claim 5, wherein the first electrode is located at a different layer from the second electrode and the third electrode, and the third electrode overlaps the first electrode.

8. The electrostatic discharge protection device according to claim 1, wherein the first electrode has a second connection portion connected to the active layer at a position opposite to the first connection portion.

9. The electrostatic discharge protection device according to claim 3, further comprising a light blocking pattern overlapping at least one of the plurality of active layer patterns under the active layer.

10. The electrostatic discharge protection device according to claim 9, wherein the light blocking pattern integrally overlaps the plurality of active layer patterns.

11. The electrostatic discharge protection device according to claim 9, wherein the light blocking pattern alternately overlaps the plurality of active layer patterns.

12. The electrostatic discharge protection device according to claim 1, wherein the at least one hole of the active layer is distributed in a region overlapping the first electrode and in a region not overlapping the first electrode in the active layer.

13. The electrostatic discharge protection device according to claim 1, wherein the active layer comprises an oxide semiconductor.

14. The electrostatic discharge protection device according to claim 13, wherein an external signal is applied to the first electrode and a power voltage is applied to the second electrode.

15. The electrostatic discharge protection device according to claim 1, wherein the first electrode and the second electrode are located at a same layer.

16. A display device, comprising:
a substrate comprising an active area comprising a plurality of sub-pixels and a non-active area adjacent to the active area; and
an electrostatic discharge protection device provided at the non-active area,
wherein the electrostatic discharge protection device comprises:
a first electrode extending in a first direction;
an active layer having a first width in the first direction, and overlapping the first electrode, wherein the active layer comprises at least one hole in an overlapping region with the first electrode, and is disposed longer outwardly than one or more sides of the first electrode in a second direction intersecting the first direction; and
a second electrode disposed parallel to the first electrode and having a first connection portion connected to one end of the active layer.

17. The display device according to claim 16, wherein the substrate comprises a pad portion and a gate-in-panel at the non-active area, and the electrostatic discharge protection device is provided between the pad portion and the gate-in-panel.

18. The display device according to claim 17, further comprising a line-on-glass block between the pad portion and the gate-in-panel.

19. The display device according to claim 16, wherein each of the plurality of sub-pixels comprises a transistor comprising an oxide semiconductor.
